(19) United States
(12) Patent Application Publication
(10) Pub. No.: US 2026/0082779 A1
(43) Pub. Date: Mar. 19, 2026

(54) Display Apparatus

(71) Applicant: LG Display Co., Ltd., Seoul (KR)

(72) Inventors: Hoon Sok Son, Paju-si (KR); Go Eun Lim, Paju-si (KR); Min Ki Kim, Paju-si (KR)

(21) Appl. No.: 19/202,696

(22) Filed: May 8, 2025

(30) Foreign Application Priority Data
Sep. 19, 2024 (KR) 10-2024-0126679

(51) Int. Cl. H10K 59/131; H10K 59/80

(52) U.S. Cl. CPC H10K 59/131; H10K 59/873

(57) ABSTRACT

Disclosed is a display apparatus configured such that a first display substrate having high resolution is disposed in the center and a second display substrate having typical resolution is disposed at an area surrounding the first display substrate, whereby the display apparatus has high resolution while being manufactured at low manufacturing costs.

### CROSS-REFERENCE TO RELATED APPLICATION

This application claims the benefit of Republic of Korea Patent Application No. 10-2024-0126679, filed on Sep. 19, 2024, which is hereby incorporated by reference in its entirety.

### BACKGROUND

### Field of the Disclosure

The present disclosure relates to a display apparatus, and more particularly to a high-resolution display apparatus with a lower manufacturing cost.

### Discussion of the Related Art

Various types and forms of display apparatuses that display images on televisions (TVs), monitors, smartphones, laptop computers, and head-mounted displays are used.

Among various types of display apparatuses, a light emitting display apparatus (LED) has a structure in which an emission layer is formed between an anode and a cathode and the emission layer emits light in response to an electric field between the two electrodes to display images.

The emission layer can be made of an organic or inorganic material in which excitons are generated by combination of electrons and holes and the generated excitons fall from an excited state to a ground state, thereby emitting light.

In order to apply such a display apparatus to a head-mounted display that implements virtual reality (VR) or augmented reality (AR), a small size and a high resolution of 3,000 pixels per inch (PPI) or more are required.

### SUMMARY

In a display apparatus applied to VR or AR, an organic light emitting diode is formed on a silicon substrate (OLEDoS) to achieve high resolution, which significantly increases the manufacturing cost compared to a display apparatus using a glass or plastic substrate.

Therefore, VR or AR is implemented by forming an organic light emitting diode on a low-cost glass substrate.

However, a glass substrate type display apparatus has the problem that it is difficult to manufacture a high-resolution display apparatus having a resolution of 1400 PPI or more.

The present disclosure discloses a display apparatus capable of realizing high resolution while having a lower manufacturing cost than the existing OLEDoS display apparatus.

It is an object of the present disclosure to provide a display apparatus configured such that a first display substrate having small-sized high-resolution pixels is disposed in a central area of a display panel where the user's gaze is focused and a low-cost second display substrate having typical resolution pixels is disposed in a surrounding area (area surrounding the central area) where the user's gaze is not focused, whereby manufacturing costs of the display apparatus are reduced.

In addition, an inclined surface can be formed on each of an outer edge of the first display substrate and an inner edge of the second display substrate, whereby the first display substrate can be accurately coupled to the second display substrate.

In addition, pads can be disposed on the outer edge of the first display substrate and the inner edge of the second display substrate so as to be electrically connected to each other, whereby a signal for driving the first display substrate can be applied through the second display substrate.

Objects of the present disclosure devised to solve the problems are not limited to the aforementioned objects, and other unmentioned objects will be clearly understood by those skilled in the art based on the following detailed description of the present disclosure.

In one embodiment, a display apparatus comprises: a first display substrate having a first display area; a second display substrate that surrounds the first display area, the second display substrate having a second display area; a first pad portion on a part of an outer edge of the first display substrate; and a second pad portion on a part of an inner edge of the second display substrate, wherein the first pad portion and the second pad portion are electrically connected to each other and in contact with each other.

In one embodiment, a display device comprises: a first display substrate including a first material, the first display substrate having a first display area with a first resolution; and a second display substrate including a second material that is different from the first material and an opening in which the first display substrate is disposed such that the second display substrate surrounds the first display substrate in a plan view of the display device, the second display substrate having a second display area with a second resolution that is less than the first resolution, wherein the first display area of the first display substrate displays a first portion of an image and the second display area of the second display substrate displays a second portion of the image that surrounds the first portion of the image.

Specific details of other embodiments are included in the detailed description and the drawings.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a plan view of a display apparatus according to an embodiment of the present disclosure;

FIG. 2 is a plan view of a first display substrate according to an embodiment of the present disclosure;

FIG. 3 is a plan view of a second display substrate according to an embodiment of the present disclosure;

FIG. 4 is a cross sectional view taken along line I-I′ of FIG. 1 according to an embodiment of the present disclosure;

FIGS. 5 to 7 are cross sectional views taken along line I-I′ of FIG. 1 in the display apparatus according to another embodiment of the present disclosure;

FIG. 8 is a cross sectional view showing the detailed coupling structure between a first display panel and a second display panel in the display apparatus according to another embodiment of the present disclosure;

FIG. 9 is an enlarged sectional view of part A of FIG. 4 according to an embodiment of the present disclosure; and

FIGS. 10 to 12 are views showing a head-mounted display including the display apparatus according to an embodiment of the present disclosure.

### DETAILED DESCRIPTION

Particular details for embodying the present disclosure will become apparent with reference to embodiments described hereinafter together with the accompanying drawings. However, the present disclosure is not limited to the embodiments disclosed herein and may be embodied in many different forms. The embodiments are provided to make the present disclosure complete and to more completely describe the scope of the present disclosure to a person having ordinary skill in the art to which the present disclosure pertains, and the claims are not limited by the embodiments of the present disclosure.

In the drawings for explaining the embodiments of the present disclosure, the illustrated shape, size, ratio, angle, and number are given by way of example, and thus, are not limitative of the disclosure of the present disclosure. Throughout the specification, the same reference numerals designate the same elements. In addition, in the following description of the present disclosure, a detailed description of known functions and configurations incorporated herein will be omitted when it may make the subject matter of the present disclosure rather unclear. The terms “comprises”, “includes”, and/or “has”, used in this specification, do not preclude the presence or addition of other elements unless used along with the term “only.” The singular forms are intended to include the plural forms as well, unless the context clearly indicates otherwise.

In the interpretation of elements included in the various embodiments of the present disclosure, the elements are interpreted as including an error range even if there is no explicit description thereof.

When describing positional relationships, for example, when the positional relationship between two parts is described using “on”, “above”, “below”, “aside”, or the like, one or more other parts may be located between the two parts unless the term “directly” or “closely”is used therewith.

References to a device or layer as being “on” another device or layer include both the case where the device or layer is directly disposed on the other device or layer and the case where the device or layer is disposed on the other device or layer with a further device or layer being interposed therebetween.

Although terms such as “first” and “second” may be used to describe various elements, the elements are not limited by these terms. These terms are merely used to distinguish an element from another element. Therefore, a first element referred to herein may also be a second component within the technical idea of the present disclosure.

Throughout the specification, the same reference numerals designate the same elements.

The size and thickness of each configuration in the drawings is shown for illustrative purposes only, and the present disclosure is not necessarily limited to the size and thickness of the configuration shown.

The respective features of the various embodiments of the present disclosure may be partially or wholly coupled to and combined with each other, and various technical linkages therebetween and operation methods thereof are possible. These various embodiments may be performed independently of each other or may be performed in association with each other.

A display apparatus according to the present disclosure is applicable to an organic light emitting display apparatus; however, the present disclosure is not limited thereto, and the display apparatus according to the present disclosure is applicable to various display apparatuses.

Hereinafter, a display apparatus according to an embodiment of the present disclosure will be described with reference to the drawings.

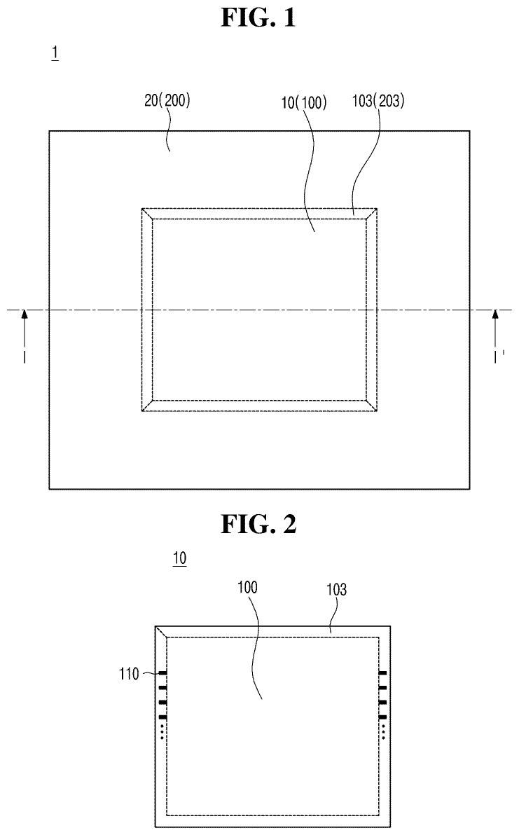

FIG. 1 is a plan view of a display apparatus according to an embodiment of the present disclosure.

Referring to FIG. 1, the display apparatus 1 according to the present disclosure can include a first display substrate 10 having a first display area 100 and a second display substrate 20 having a second display area 200. The second display area 200 surrounds the first display area 100 according to one embodiment.

The first display area 100 can be formed on the entirety of an upper surface of the first display substrate 10. The second display area 200 can be formed on the entirety of an upper surface of the second display substrate 20 or on an area excluding an outer edge of the second display substrate 20. The outer edge of the second display substrate 20 can be a bezel area where an image is not displayed. A circuit board can be connected to the bezel area of the second display substrate 20. The second display area 200 can be formed smaller than the upper surface of the second display substrate 20.

The first display substrate 10 can be formed to have square shape, but the shape of the first display substrate 10 is not limited thereto. The outer side of the second display substrate 20 can be formed to have square shape, and the inner side of the second display substrate 20 can be opened so as to correspond to the first display substrate 10. For example, the plane of the second display substrate 20 can be formed in the shape of a picture frame or a donut. The inner side of the second display substrate 20 can be formed in the shape of a recess so as to correspond to the shape of the first display substrate 10. Thus, the second display substrate 20 includes an opening where the first display substrate 10 is disposed. While the first display substrate 10 is disposed in the opening, the second display substrate 20 surrounds the first display substate 10 in a plan view.

That is, a central area of the second display substrate 20 can be open or removed, and the second display substrate 20 can be formed to surround the first display substrate 10. However, the shape of the second display substrate 20 is not limited thereto, and the second display substrate 20 can have various shapes corresponding to the shape of the first display substrate 10. For example, the second display substrate 20 can be formed to surround the first display substrate 10 while supporting the first display substrate 10 from below.

The display apparatus 1 according to the embodiment of the present disclosure can be a display apparatus 1 for implementing VR or AR. For example, the display apparatus 1 according to the embodiment of the present disclosure can be applied to a head-mounted display (HMD) disposed at a short distance in front of the user's eyes to implement VR or AR.

Since the user's focus is formed at a short distance in front of the user's eyes looking at the display apparatus 1, the display apparatus 1 must implement a high-resolution image. For the display apparatus 1 that implements the high-resolution image, a drive circuit, such as a thin-film transistor, can be formed using a semiconductor process. Since the display substrate must use a silicon wafer in order to use the semiconductor process, the manufacturing costs of the display apparatus 1 increase.

An increase in manufacturing costs can weaken the product competitiveness of the display apparatus 1. Therefore, in order to manufacture the display apparatus 1 at low manufacturing costs while implementing high-resolution VR or AR, a silicon wafer substrate with high resolution can be used as the first display substrate 10, and a glass or plastic substrate with typical resolution that can be used as the second display substrate 20. That is, the first display substrate 10 has a first resolution and the second display substrate has a second resolution that is less than the first resolution. Thus, the first display substrate 10 includes a first material for displaying a portion of an image at high resolution and the second display substrate 20 includes a second material that is different than the first material for displaying a portion of the image with a low resolution that is less than the first resolution.

Generally, users looking at the display apparatus 1 tend to focus their gaze on the central area of the display apparatus 1, and a surrounding area can be less focused on than the central area. Therefore, a wafer substrate that can achieve high resolution can be used as the first display substrate 10 located in the central area where the users are typically focusing their gaze, and a glass or plastic substrate that can achieve typical resolution can be used as the second display substrate 20 located in the surrounding area.

The display apparatus 1 or display device according to the embodiment of the present disclosure can be configured such that the first display substrate 10 in the central area and the second display substrate 20 in the surrounding area are coupled to each other. An image displayed on the first display substrate 10 and an image displayed on the second display substrate 20 must appear seamless and natural. In one embodiment, a first portion of the image is displayed on the first display substrate 10 and a second portion of the image is displayed on the second display substrate 20 where the first portion and the second portion collectively form the entire image that is dislayed by the display apparatus 1.

If the first display substrate 10 and the second display substrate 20 are coupled to each other in a misaligned state, an image displayed on the display apparatus 1 can be an unnatural image recognizing image discontinuities, such as a boundary line between the first display substrate 10 and the second display substrate 20. Therefore, it is important to couple the first display substrate 10 and the second display substrate 20 to each other in an accurately aligned state.

In order to accurately dispose the first display substrate 10 in the central area of the second display substrate 20, a part of the outer side (e.g., an outer edge) of the first display substrate 10 can include a first inclined surface 103, and a part of the inner side (e.g., an inner edge) of the second display substrate 20 can include a second inclined surface 203 corresponding to the first inclined surface 103 formed on the part of the outer side of the first display substrate 10. That is, an outer perimeter of the first display substrate 10 is inclined and an inner perimeter of the second display substrate 20 that corresponds to an opening in the second display substate 20 in which the first display substrate 10 is disposed is also inclined. The inclined outer perimeter of the first display substate 10 and the inclined inner perimeter of the second display substate 10 overlap each other to align the first display substrate and the second display substrate 20. In one embodiment, at least a portion of the inclined outer perimeter of the first display substate 10 and at least a portion of the inclined inner perimeter of the second display substate 10 are in direct contact with each other.

The first inclined surface 103 can be formed in a negative taper shape and the second inclined surface 203 can be formed in normal positive taper shape. A lower surface of the first display substrate 10 can have a size that is smaller than a size of the upper surface of the first display substrate 10 due to the first inclined surface 103 at the outer side or end of the first display substrate 10. For example, the first display area 100 can have a larger size than the lower surface of the first display substrate 10. When the first display substrate 10 is moved downward and coupled to the second display substrate 20, the first inclined surface 103 of the first display substrate 10 can move along the second inclined surface 203 of the second display substrate 20, whereby the first display substrate 10 can be accurately disposed in the central area of the second display substrate 20.

If the first display substrate 10 is accurately disposed in the central area of the second display substrate 20, an image displayed on the first display substrate 10 and an image displayed on the second display substrate 20 can be displayed seamlessly and naturally, and the upper surface of the first display substrate 10 and the upper surface of the second display substrate 20 can be disposed at the same height, whereby unity can be felt in the external appearance of the display apparatus 1.

FIG. 2 is a plan view of a first display substrate according to an embodiment of the present disclosure.

Referring to FIG. 2, the first display substrate 10 according to the present disclosure can be a silicon wafer substrate. A first thin-film transistor layer, a first emission layer, and a first color filter layer can be stacked on the first display substrate 10 to constitute a first display panel.

A first inclined surface 103 can be formed in an edge area, which is an outer area of the first display substrate 10. The first inclined surface 103 can be formed in the entirety of the edge area or in a part of the edge area. Thus, the first inclined surface 103 is disposed around the entire outer perimeter of the first display substrate 10.

A first pad portion 110 can be formed on a part of the outer side of the first display substrate 10. The first pad portion 110 can be formed on the first inclined surface 103 of the first display substrate 10 and the first pad portion 110 can be provided in plural. That is, a plurality of first pad portions 110 are disposed on the first inclined surface 103. The first pad portion 110 can be disposed to apply a drive signal to the first thin-film transistor layer stacked on the first display substrate 10 and the first pad portion 110 can be electrically connected to a first circuit board configured to supply the drive signal and the first thin-film transistor layer.

FIG. 2 shows the first pad portion 110 being disposed in left and right areas in the plan view of the display device. However, the present disclosure is not limited thereto, and the first pad portion 110 can be disposed in at least one of upper, lower, left, and right areas in the plan view.

The first display area 100 can be formed on an upper surface of the first display substrate 10. The first display area 100 is an area that can be formed by the first emission layer stacked on the first display substrate 10, and can be formed to be the same size as or larger than the upper surface of the first display substrate 10. For example, the first display area 100 can be formed on the entirety of an upper surface of the first display panel.

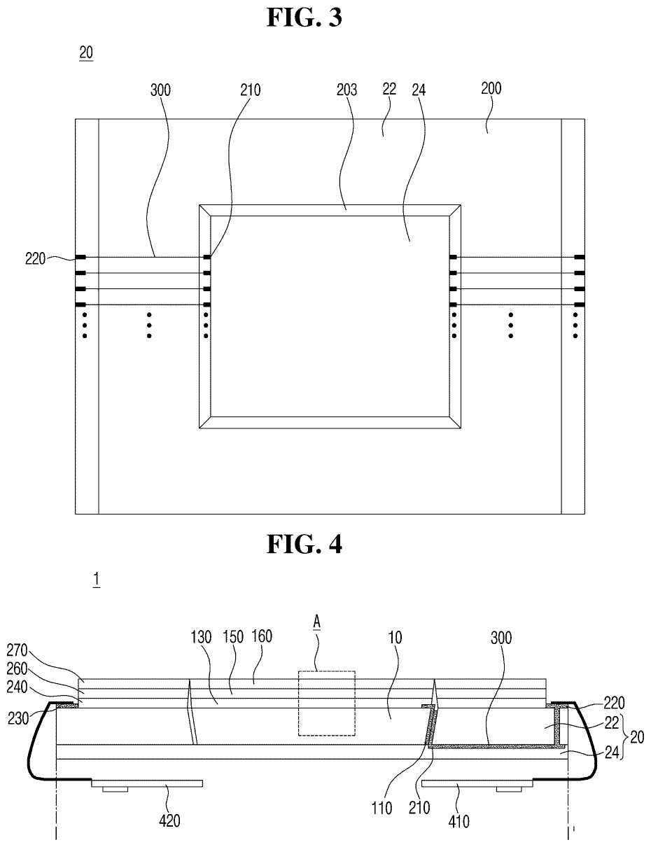

FIG. 3 is a plan view of the second display substrate 20 according to an embodiment of the present disclosure.

Referring to FIG. 3, the second display substrate 20 according to the present disclosure can be a glass substrate or a plastic substrate, and a second thin-film transistor layer, a second emission layer, and a second color filter layer can be stacked on the second display substrate 20 to constitute a second display panel.

A second inclined surface 203 can be formed in an inner edge area of the second display substrate 20. The second inclined surface 203 can be formed in the entirety of the inner edge area or in a part of the inner edge area. That is, the second inclined surface 203 is formed around the entire inner perimeter corresponding to the opening in the second display substrate 20.

A second pad portion 210 can be formed on a part of the inner side of the second display substrate 20. The second pad portion 210 can be formed on the second inclined surface 203 of the second display substrate 20, and the second pad portion 210 can be provided in plural. That is, a plurality of second pad portions 210 are disposed on the second inclined surface 203. The first pad portion 110 of the first display substrate 10 and the second pad portion 210 of the second display substrate 20 can be electrically connected to each other and in contact with each other. That is, the first pad portion 110 and the second pad portion are in contact with each other thereby electrically connecting the first display substrate 10 (e.g., the first display panel) and the second display substrate 20 (e.g., the second display panel).

The second pad portion 210 of the second display substrate 20 can be formed at the position corresponding to the first pad portion 110 of the first display substrate 10, and the second pad portion 210 and the first pad portion 110 can be in one-to-one contact. That is, each of a plurality of second pad portions 210 can be in one-to-one contact with a corresponding one of a plurality of first pad portions 110.

One end (e.g., a first end) of a pad wire 300 is connected to the second pad portion 210 to supply a drive signal to the second pad portion 210 can be formed under the second display substrate 20. The pad wire 300 can extend along a lower surface of the second display substrate 20 and can be connected to the second pad portion 210.

A third pad portion 220 can be formed on a part of the outer side or outer edge of the second display substrate 20. The third pad portion 220 can be attached to a first circuit board, and a signal for driving the first display substrate 10 can be applied thereto.

The third pad portion 220 can be connected to another end (e.g., a second end) of the pad wire 300, and a drive signal generated by the first circuit board can be transmitted to the first thin-film transistor layer of the first display substrate 10 via the third pad portion 220, the pad wire 300, the second pad portion 210, and the first pad portion 110.

The third pad portion 220 can be disposed so as to correspond to the second pad portion 210. For example, if the second pad portion 210 is formed in left and right areas of the inner side of the second display substrate 20, the third pad portion 220 can be formed in left and right areas of the outer side the second display substrate 20.

The third pad portion 220 can be formed on an area of the second display substrate 20 from which the second thin-film transistor layer, the second emission layer, etc. have been removed. The area from which the second thin-film transistor layer, the second emission layer, etc. have been removed can be a bezel area of the second display substrate 20.

FIG. 4 is a sectional view taken along line I-I′ of FIG. 1 according to one embodiment.

Referring to FIG. 4, the display apparatus 1 according to the present disclosure can include a first display substrate 10 and a second display substrate 20 disposed so as to surround the first display substrate 10.

The second display substrate 20 can include an upper display substrate 22 and a lower display substrate 24. The lower display substrate 24 can be flat, and can be formed so as to occupy the entire area of the display apparatus 1 without an opening. The upper display substrate 22 can be disposed on the lower display substrate 24, and a portion of the upper display substrate 22 such as a central area thereof can be open while having an inclined surface. Thus, an opening is formed through an entire thickness of the upper display substrate 22.

The first display substrate 10 can be disposed on the lower display substrate 24, and the upper display substrate 22 can be formed so as to surround the first display substrate 10. In one embodiment, the first display substrate 10 contacts the upper surface of the lower display substrate 24 while disposed in the opening in the upper display substrate 22.

The third pad portion 220 configured to apply a drive signal to the first display substrate 10 can be formed on an upper surface of the upper display substrate 22, and the third pad portion 220 can extend through the upper display substrate 22 in a thickness direction to a lower surface of the upper display substrate 22 so as to be connected to the pad wire 300.

The pad wire 300 can be formed on the lower surface of the upper display substrate 22 and can be disposed between the upper display substrate 22 and the lower display substrate 24. The pad wire 300 can extend so as to be connected to the second pad portion 210, and the second pad portion 210 can be electrically connected to the first pad portion 110 in contact therewith.

The first pad portion 110 can be connected to the first thin-film transistor layer 130 formed on the first display substrate 10 to apply a signal to a circuit wire and a drive circuit included in the first thin-film transistor layer 130. The drive circuit may include one or more transistors for example.

A first emission layer 150 can be disposed on the first thin-film transistor layer 130, and the first emission layer 150 can emit light according to a signal applied to the first thin-film transistor layer 130. A first color filter layer 160 can be disposed on the first emission layer 150 to change the light emitted by the first emission layer 150 to a desired color.

The first display substrate 10, the first thin-film transistor layer 130, the first emission layer 150, and the first color filter layer 160 are stacked to constitute a first display panel.

A first circuit board 410 can be connected to the third pad portion 220. The first circuit board 410 can be connected to the third pad portion 220 using a tape automated bonding (TAB) method, can be connected to the third pad portion 220 using a chip-on-glass (COG) method or a chip-on-panel (COP) method, or can be connected to the third pad portion 220 using a chip-on-film (COF) method.

A fourth pad portion 230 configured to apply a drive signal to the second display substrate 20 can be formed on the second display substrate 20, and can be formed on the opposite side of the third pad portion 220. The fourth pad portion 230 can be formed in various areas of the second display substrate 20, and the disposition position thereof is not limited to any one position.

The fourth pad portion 230 can be connected to a second thin-film transistor layer 240 formed on the second display substrate 20 to apply a signal to a circuit wire and a drive circuit included in the second thin-film transistor layer 240.

A second emission layer 260 can be disposed on the second thin-film transistor layer 240, and the second emission layer 260 can emit light according to a signal applied to the second thin-film transistor layer 240. A second color filter layer 270 can be disposed on the second emission layer 260 to change the light emitted by the second emission layer 260 to a desired color.

The second display substrate 20, the second thin-film transistor layer 240, the second emission layer 260, and the second color filter layer 270 can be stacked to constitute a second display panel.

A signal for driving the second display substrate 20 can be applied to the fourth pad portion 230, and a second circuit board 420 configured to drive the second display substrate 20 can be connected to the fourth pad portion 230. The second circuit board 420 can be connected to the fourth pad portion 230 using a tape automated bonding (TAB) method, can be connected to the fourth pad portion 230 using a chip-on-glass (COG) method or a chip-on-panel (COP) method, or can be connected to the fourth pad portion 230 using a chip-on-film (COF) method.

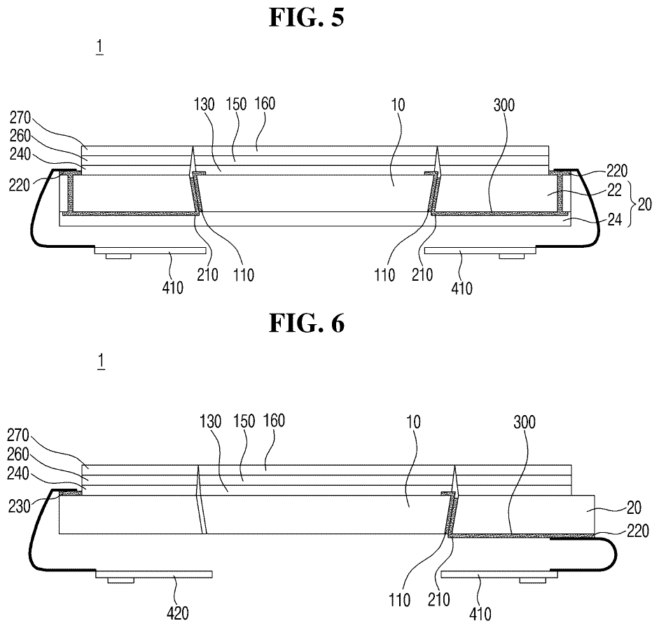

FIGS. 5 to 7 are sectional views of display apparatuses according to other embodiments of the present disclosure, taken along line I-I′ of FIG. 1.

Referring to FIG. 5, the display apparatus 1 according to this embodiment can be configured such that, in order to increase the size thereof or to realize a high refresh rate, a first pad portion 110 is disposed on the left and right sides of a first display substrate 10 to drive a first display panel in a double feeding mode. That is, a first pad portion 110 is disposed at a first side of the first display substrate 10 and another first pad portion 110 is disposed at a second side of the first display substrate 10. For example, a drive signal can be applied through the first pad portion 110 on the left side to drive a left half area of the display apparatus 1, and a drive signal can be applied through the first pad portion 110 on the right side to drive a right half area of the display apparatus 1.

However, the formation position of the first pad portion 110 is not limited thereto, and the first pad portion 110 can be formed in two or more of upper, lower, left, or right areas in plan.

The configuration of connection from a first circuit board 410 to the first pad portion 110 can be the same as that shown in FIG. 4. In order to simplify the configuration of connection from the first circuit board 410 to the first pad portion 110, a second pad portion 210 and a third pad portion 220 can be formed so as to correspond in position to the first pad portion 110.

Referring to FIG. 6, a third pad portion 220 according to the present disclosure can be disposed under a second display substrate 20 to remove one bezel area of a second display substrate 20.

The third pad portion 220 can be disposed on the same layer as a pad wire 300 so as to be connected to the pad wire 300. The pad wire 300 and the third pad portion 220 are disposed on a lower surface of the second display substrate 20. The third pad portion 220 can be connected to a first circuit board 410 to supply a signal for driving a first display substrate 10 to a second pad portion 210. In order to attach the first circuit board 410 to the third pad portion 220, the second display substrate 20 can be constituted by an upper display substrate without a lower display substrate.

If the second display substrate 20 is constituted by the upper display substrate without the lower display substrate, the durability of the second display substrate 20 and the supporting force of the first display substrate 10 can be reduced, but the overall thickness of the display apparatus 1 can be reduced, which is advantageous.

A fourth pad portion 230 can be formed on the side of the second display substrate 20 opposite the third pad portion 220. The fourth pad portion 230 can be formed in various areas of the second display substrate 20, and the formation position thereof is not limited to any one position.

The fourth pad portion 230 can be connected to a second thin-film transistor layer 240, and can apply a signal to a circuit wire and a drive circuit included in the second thin-film transistor layer 240.

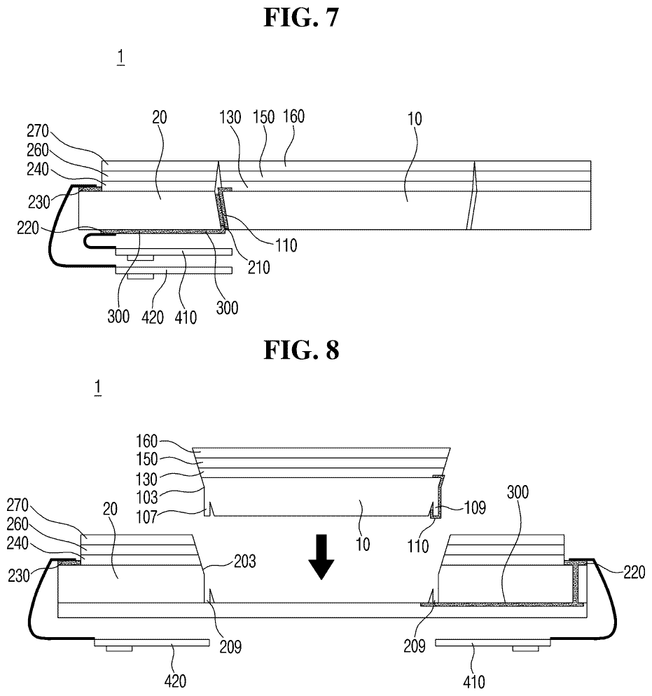

FIG. 7 shows a display apparatus according to another embodiment of the present disclosure, wherein a third pad portion 220 and a fourth pad portion 230 are disposed on one side of the display apparatus 1 to remove one bezel area of the display apparatus 1. The third pad portion 220 can be disposed on the same layer as a pad wire 300 so as to be connected to the pad wire 300. The third pad portion 220 can be connected to a first circuit board 410 to supply a signal for driving a first display substrate 10 to a second pad portion 210.

The fourth pad portion 230 can be formed in the same area as the area of a second display substrate 20 where the third pad portion 220 is located.

The fourth pad portion 230 can be connected to a second thin-film transistor layer 240 formed on the second display substrate 20 to apply a signal to a circuit wire and a drive circuit included in the second thin-film transistor layer 240.

The fourth pad portion 230 can be connected to a second circuit board 420 to supply a signal for driving the second display substrate 20, and the second circuit board 420 can be disposed under the first circuit board 410.

FIG. 8 is a cross sectional view of a display apparatus according to another embodiment of the present disclosure, wherein the detailed coupling structure between a first display panel and a second display panel is shown.

Referring to FIG. 8, a first inclined surface 103 of a first display substrate 10 according to the present disclosure or the edge of a rear surface of the first display substrate 10 can further include protrusions 107 and 109. The protrusions of the first display substrate 10 can include a positioning protrusion 107 and a contact protrusion 109. The positioning protrusion 107 can be a protrusion for accurately coupling the first display substrate 10 to a second display substrate 20, and can have no pad portion. The contact protrusion 109 can be a protrusion capable of applying a drive signal to a first thin-film transistor layer 130 while accurately coupling the first display substrate 10 to the second display substrate 20. The contact protrusion 109 can be provided with a first pad portion 110 or can be coated with a metal layer, and can be electrically connected to a second pad portion or a pad wire 300 formed on the second display substrate 20.

A second inclined surface 203 of the second display substrate 20 or the inner side of the second display substrate 20 can further include recesses 209. The recesses 209 can be formed at the position corresponding to the protrusions 107 and 109 formed on the first display substrate 10, and the protrusions 107 and 109 of the first display substrate 10 can be inserted into the recesses 209, whereby the first display substrate 10 and the second display substrate 20 can be accurately coupled to each other. That is, the protrusions 107 and 109 of the first display substrate 10 can be coupled to the recesses 209 of the second display substrate 20, whereby the first display substrate 10 can be accurately coupled to the open area of the inner side of the second display substrate 20. In other words, each of the protrusions 107 and 109 is disposed within one of the recesses 209 to connect together the first display substrate 10 and the second display substrate 20.

The protrusions including the positioning protrusion 107 and the contact protrusion 109 and the recesses 209 can be implemented in various forms such as a star shape or a cross shape depending on the coupling structure, position, and effect. The positioning protrusion 107 and the contact protrusion 109 can be disposed in a mixture of various forms. For example, the contact protrusion 109 can be formed in a straight line shape, and a star-shaped positioning protrusion 107 can be formed above and under the contact protrusion 109.

A first pad portion 110 connected to the first thin-film transistor layer 130 can be formed on the surface of the contact protrusion 109 of the first display substrate 10, and the first pad portion 110 formed on the contact protrusion 109 can be in contact with the pad wire 300 disposed under the recess 209 of the second display substrate 20 such that a drive signal is supplied. Thus, the first pad portion 110 is in contact with the contact protrusion 109 but not the positioning protrusion 107. A metal layer can be formed on an inner surface of the recess 209 to form a second pad portion connected to the pad wire 300. The second pad portion can be electrically connected to the first pad portion 110 in contact therewith.

A first thin-film transistor layer 130, a first emission layer 150, and a first color filter layer 160 can be stacked on the first display substrate 10, and ends of the components disposed on the first display substrate 10 can each have an inclined surface extending from the first inclined surface 103. Alternatively, the ends of the components disposed on the first display substrate 10 can each be formed as a vertical surface rather than an inclined surface.

If the ends of the components disposed on the first display substrate 10 each have an inclined surface, ends of a second thin-film transistor layer 240, a second emission layer 260, and a second color filter layer 270 disposed on the second display substrate 20 can also each have an inclined surface corresponding thereto.

That is, the end of the first display panel including the first display substrate 10 and the end of the second display panel including the second display substrate 20 can each have an inclined surface, whereby the first display substrate 10 and the second display substrate 20 can be more accurately coupled to each other.

One of the configurations shown in FIGS. 1 to 7 can be adopted as a configuration for applying a drive signal to each of the first thin-film transistor layer 130 and the second thin-film transistor layer 240.

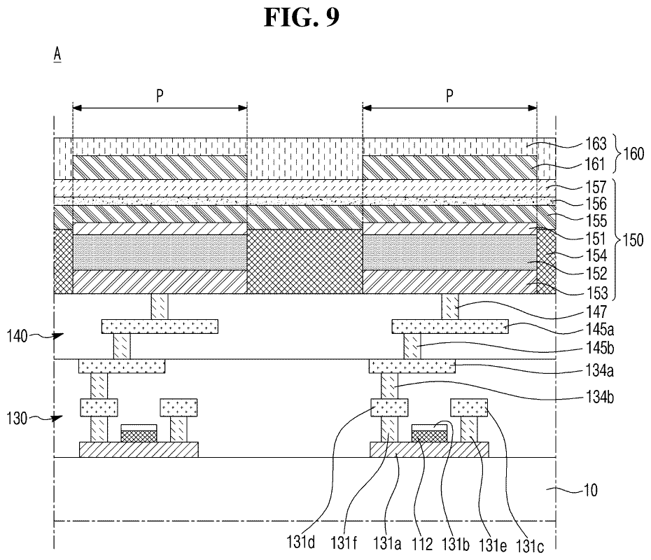

FIG. 9 is an enlarged sectional view of part A of FIG. 4, showing the detailed configuration of the first display panel according to one embodiment.

Referring to FIG. 9, a first thin-film transistor layer 130 can be formed on a first display substrate 10, which is a silicon wafer substrate. The first thin-film transistor layer 130 can include an active layer 131a, a gate electrode 131b, a source electrode 131c, and a drain electrode 131d. FIG. 9 illustrates that the first thin-film transistor layer has a top gate structure in which the gate electrode 131b is located above the active layer 131a; however, the present disclosure is not limited thereto. The first thin-film transistor layer 130 can have a bottom gate structure in which the gate electrode 131b is located under the active layer 131a or a double gate structure in which the gate electrode 131b is located above and under the active layer 131a.

The active layer 131a can be formed on the first display substrate 10. The active layer 131a can be made of a silicon-based semiconductor material or an oxide-based semiconductor material. A gate insulating film 112 can be formed on the active layer 131a. The gate insulating film 112 can be made of an inorganic film, such as a silicon oxide film (SiOx), a silicon nitride film (SiNx), or multiple layers thereof. The gate electrode 131b can be formed on the gate insulating film 112.

The source electrode 131c can be connected to the active layer 131a via a contact hole 131e. The drain electrode 131d can be connected to the active layer 131a via a contact hole 131f. The active layer 131a, the gate electrode 131b, the source electrode 131c, and the drain electrode 131d can be insulated from each other by an insulating film formed therebetween.

A first connecting metal layer 134a can be disposed on the first thin-film transistor layer 130.

The first connecting metal layer 134a can be connected to the drain electrode 131d via a contact hole 134b.

A first insulating layer 140 can be formed on the first thin-film transistor layer 130. The first insulating layer 140 can be located between the first thin-film transistor layer 130 and a first emission layer 150 to connect a drive signal generated by the first thin-film transistor layer 130 while entirely insulating the first thin-film transistor layer 130 and the first emission layer 150 from each other.

The first insulating layer 140 can include an insulating material formed on a second connecting metal layer 145a and the other areas.

The first connecting metal layer 134a can be connected to the second connecting metal layer 145a via a contact hole 145b. The first connecting metal layer 134a and the second connecting metal layer 145a can be insulated from each other by an insulating material. The first insulating layer 140 can be omitted, and the drain electrode 131d can be directly connected to the first emission layer 150.

A first electrode 151 can be disposed on the first insulating layer 140. The first electrode 151 can be connected to the second connecting metal layer 145a via a contact hole 147. The first electrode 151 can be made of a transparent conductive material (TCO) capable of transmitting light, such as ITO or IZO.

A display apparatus having a top emission structure in which light emitted by an organic emission layer 155 is directed upwards has been illustrated as the organic light emitting display apparatus according to the embodiment of the present disclosure. In the top emission structure, a reflective electrode 152 can be disposed under the first electrode 151 in order to reflect the light emitted downward and to implement the microcavity effect. The reflective electrode 152 can be made of a metal material having high reflectance, such as silver (Ag).

A buffer electrode 153 can be disposed under the reflective electrode 152. The buffer electrode 153 can be formed so as to have a double-layer structure of titanium (Ti) and titanium nitride (TiN). The buffer electrode 153 can be omitted.

The first electrode 151, the reflective electrode 152, and the buffer electrode 153 can be formed in a vertical structure. A planarization layer 154 can be disposed next to the first electrode 151 in order to level the step caused by the first electrode 151, the reflective electrode 152, and the buffer electrode 153.

An organic emission layer 155 can be formed on the first electrode 151 and the planarization layer 154. The organic emission layer 155 can include a hole transport layer, an emission layer, and an electron transport layer. In this case, when voltage is applied to the first electrode 151 and a second electrode 156, holes and electrons move to the emission layer through the hole transport layer and the electron transport layer, respectively, and combine with each other in the emission layer to emit light.

The organic emission layer 155 can be a white emission layer that emits white light. In this case, the organic emission layer 155 can be a common layer formed in common at pixels P.

If the organic emission layer 155 is a white emission layer, the organic emission layer can be formed so as to have a tandem structure including two or more stacks. Each of the stacks can include a hole transport layer, at least one emission layer, and an electron transport layer. In addition, a charge generation layer can be formed between the stacks. The charge generation layer can include an n-type charge generation layer located adjacent to the lower stack and a p-type charge generation layer formed on the n-type charge generation layer so as to be located adjacent to the upper stack. The n-type charge generation layer injects electrons into the lower stack, and the p-type charge generation layer injects holes into the upper stack. The n-type charge generation layer can be formed by an organic layer doped with an alkali metal, such as Li, Na, K, or Cs, or an alkaline earth metal, such as Mg, Sr, Ba, or Ra. The p-type charge generation layer can be formed by an organic material having a hole transport ability doped with a dopant.

The second electrode 156 can be disposed on the organic emission layer 155. The second electrode 156 can be a common layer formed in common at the pixels P. The second electrode 156 can be made of a transparent conductive material (TCO) capable of transmitting light, such as ITO or IZO, or a semi-transmissive conductive material such as magnesium (Mg), silver (Ag), or an alloy of magnesium (Mg) and silver (Ag). If the second electrode 156 is made of a semi-transmissive conductive material, the microcavity effect can be achieved.

An encapsulation film 157 can be disposed on the second electrode 156. The encapsulation film 157 can prevent oxygen or moisture from penetrating the organic emission layer 155 and the second electrode 156. To this end, the encapsulation film 157 can include at least one inorganic film and at least one organic film.

A first color filter layer 160 can be formed on the encapsulation film 157. The first color filter layer 160 can include a color filter 161 and an overcoat layer 163.

The color filter 161 can be disposed so as to correspond to a pixel P. For example, a red color filter can be disposed so as to correspond to a red pixel, a green color filter can be disposed so as to correspond to a green pixel, and a blue color filter can be disposed so as to correspond to a blue pixel.

The overcoat layer 163 can be formed to level the step caused by the color filter 161.

The first display panel can include a plurality of pixels P having the same stack structure as the pixel P described above.

FIGS. 10 to 12 are views showing a head-mounted display including the display apparatus according to the present disclosure.

Referring to FIG. 10, the head-mounted display according to the embodiment of the present disclosure includes a storage case 500 and a head-mounted band 600.

The storage case 500 receives the display apparatus, a lens array, and an eyepiece therein.

The head-mounted band 600 can be fixed to the storage case 500. The head-mounted band 600 is illustrated as being formed so as to surround an upper surface and side surfaces of a user's head; however, the present disclosure is not limited thereto. The head-mounted band 600 is configured to fix the head-mounted display to the user's head and can be replaced by a glasses type structure or a helmet type structure.

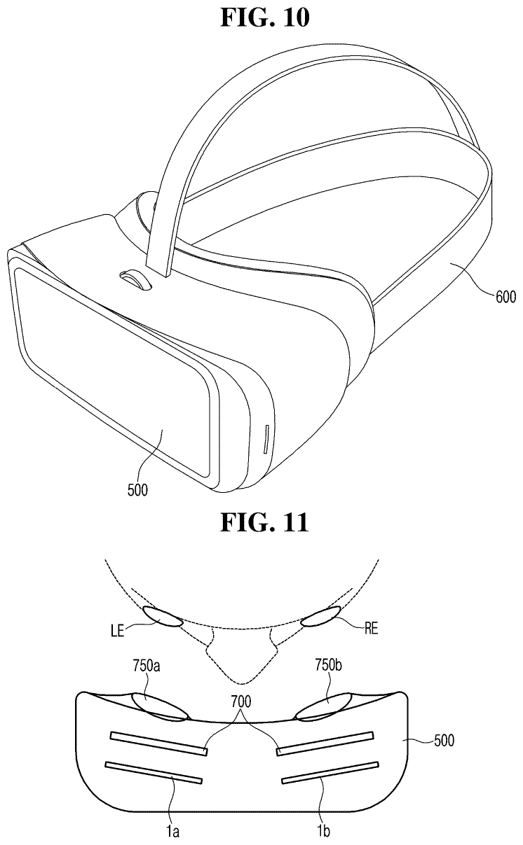

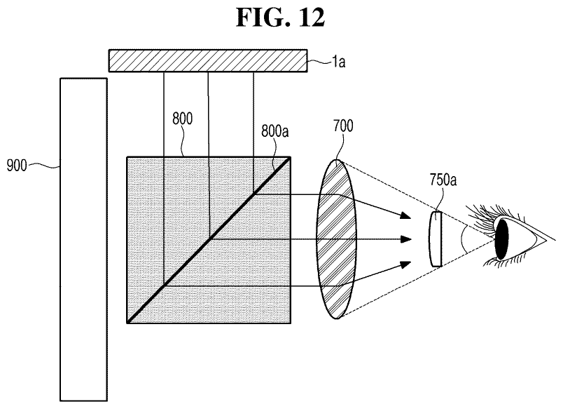

Referring to FIG. 11, a head-mounted display having a VR structure according to the present disclosure can include a left-eye display apparatus 1a and a right-eye display apparatus 1b, a lens array 700, and a left-eye eyepiece 750a and a right-eye eyepiece 750b.

The left-eye display apparatus 1a, the right-eye display apparatus 1b, the lens array 700, the left-eye eyepiece 750a, and the right-eye eyepiece 750b are stored in the storage case 500.

The left-eye display apparatus 1a and the right-eye display apparatus 1b can display the same image, in which case a user can view a 2D image. Alternatively, the left-eye display apparatus 1a can display a left-eye image and the right-eye display apparatus 1b can display a right-eye image, in which case the user can view a stereoscopic image. Each of the left-eye display apparatus 1a and the right-eye display apparatus 1b can be constituted by the display apparatus 1 according to FIGS. 1 to 9.

The lens array 700 can be disposed between the left-eye eyepiece 750a and the left-eye display apparatus 1a while being spaced apart from the left-eye eyepiece 750a and the left-eye display apparatus 1a.

In addition, the lens array 700 can be disposed between the right-eye eyepiece 750b and the right-eye display apparatus 1b while being spaced apart from the right-eye eyepiece 750b and the right-eye display apparatus 1b. The lens array 700 can be a microlens array. The lens array 700 can be replaced by a pin hole array. The image displayed on the left-eye display apparatus 1a or the right-eye display apparatus 1b can be visible to the user in an enlarged state by the lens array 700.

A left eye LE of the user can be located at the left-eye eyepiece 750a, and a right eye RE of the user can be located at the right-eye eyepiece 750b.

Referring to FIG. 12, a head-mounted display apparatus having an AR structure according to the present disclosure includes a left-eye display apparatus 1a, a lens array 700, a left-eye eyepiece 750a, a transflective unit 800, and a transmissive window 900. FIG. 12 shows only the left-eye side configuration for convenience, and a right-eye side configuration is the same as the left-eye side configuration.

The left-eye display apparatus 1a, the lens array 700, the left-eye eyepiece 750a, the transflective unit 800, and the transmissive window 900 can be stored in the storage case 500.

The left-eye display apparatus 1a can be placed on one side, e.g., an upper side, of the transflective unit 800 without screening the transmissive window 900. Therefore, the left-eye display apparatus 1a can provide an image to the transflective unit 800 without screening the external background seen through the transmissive window 900.

The lens array 700 can be disposed between the left-eye eyepiece 750a and the transflective unit 800. The transflective unit 800 can be disposed between the lens array 700 and the transmissive window 900. The transflective unit 800 can include a reflective surface 800a configured to transmit some of light while reflecting some of the light. The reflective surface 800a can be formed such that the image displayed on the left-eye display apparatus 1a moves to the lens array 700. Therefore, the user can view both the external background and the image displayed by the left-eye display apparatus 1a through the transmissive window 900. That is, the user can view the real background and the virtual image overlaid as a single image, whereby augmented reality (AR) can be realized.

As is apparent from the above description, according to an embodiment of the present disclosure, a first display substrate having high resolution and a low-cost second display substrate having typical resolution can be disposed to provide an overall low-cost high-resolution display apparatus. Therefore, it is possible to secure price competitiveness in the display market for implementing VR or AR.

In addition, the first display substrate for a central area and the second display substrate for a surrounding area, which are separated from each other, can be accurately coupled to each other, and a drive signal can be applied to the first display substrate without an additional signal wire.

Effects of the present disclosure are not limited by the above mentioned effects, and more various effects are included in the present disclosure.

Although the embodiments of the present disclosure have been described in more detail with reference to the accompanying drawings, the present disclosure is not necessarily limited to these embodiments, and can be implemented in various ways within the scope of the technical idea of the present disclosure. Consequently, the embodiments of the present disclosure are not intended to limit the technical idea of the present disclosure, but are intended to explain technical idea of the present disclosure, and the scope of the technical idea of the present disclosure is not limited by these embodiments. Therefore, the embodiments described above must be understood as illustrative, not restrictive, in all respects. The scope of protection of the present disclosure should be interpreted based on the claims, and all technical ideas within the equivalent scope should be interpreted as being included in the scope of protection of the present disclosure.

What is claimed is:

1. A display apparatus comprising:
a first display substrate having a first display area;
a second display substrate that surrounds the first display area, the second display substrate having a second display area;
a first pad portion on a part of an outer edge of the first display substrate; and
a second pad portion on a part of an inner edge of the second display substrate,
wherein the first pad portion and the second pad portion are electrically connected to each other and in contact with each other.

2. The display apparatus according to claim 1, wherein the part of the outer edge of the first display substrate comprises a first inclined surface and the part of the inner edge of the second display substrate comprises a second inclined surface that overlaps the first inclined surface.

3. The display apparatus according to claim 1, wherein the second pad portion includes a plurality of second pad portions and the first pad portion includes a plurality of first pad portions, wherein each of the plurality of second pad portions is in contact with a corresponding one of the plurality of first pad portions.

4. The display apparatus according to claim 1, further comprising:
a pad wire extending along a lower surface of the second display substrate, the pad wire including a first end that is connected to the second pad portion.

5. The display apparatus according to claim 4, further comprising:
a third pad portion and a fourth pad portion disposed on a part of an outer edge of the second display substrate,
wherein the third pad portion receives a signal that drives the first display substrate and the fourth pad portion receives a signal that drives the second display substrate.

6. The display apparatus according to claim 5, wherein the pad wire extends through the second display substrate and includes a second end that is connected to the third pad portion.

7. The display apparatus according to claim 1, further comprising:
a first subpixel on the first display substrate, the first subpixel having a first size; and
a second subpixel on the second display substrate, the second subpixel having a second size that is larger than the first size.

8. The display apparatus according to claim 7, wherein the first subpixel comprises a first thin-film transistor, a first insulating layer, a first emission layer, and a first encapsulation layer,
wherein the second subpixel comprises a second thin-film transistor, a second insulating layer, a second emission layer, and a second encapsulation layer,
wherein an end of the first subpixel and an end of the second subpixel each comprises a vertical surface or an inclined surface.

9. The display apparatus according to claim 1, wherein an upper surface of the first display substrate and an upper surface of the second display substrate are at a same height.

10. The display apparatus according to claim 1, wherein the second display substrate comprises:
an upper display substrate; and
a lower display substrate,
wherein the first display substrate is on the lower display substrate and the upper display substrate surrounds the first display substrate.

11. The display apparatus according to claim 1, wherein the first display substrate is a wafer substrate and the second display substrate is a glass substrate or a plastic substrate.

12. The display apparatus according to claim 2, wherein the first inclined surface of the first display substrate or a rear surface of the first display substrate further comprises a protrusion, and the second inclined surface of the second display substrate or a surface of the second display substrate further comprises a recess, and
wherein the protrusion of the first display substrate is disposed in the recess of the second display substrate.

13. The display apparatus according to claim 12, wherein the protrusion comprises a positioning protrusion and a contact protrusion,
wherein the first pad portion is in contact with the contact protrusion but not the positioning protrusion.

14. A display device comprising:
a first display substrate including a first material, the first display substrate having a first display area with a first resolution; and
a second display substrate including a second material that is different from the first material and an opening in which the first display substrate is disposed such that the second display substrate surrounds the first display substrate in a plan view of the display device, the second display substrate having a second display area with a second resolution that is less than the first resolution,
wherein the first display area of the first display substrate displays a first portion of an image and the second display area of the second display substrate displays a second portion of the image that surrounds the first portion of the image.

15. The display device according to claim 14, wherein the first material comprises a silicon wafer and the second material comprises a glass substrate or a plastic substrate.

16. The display device according to claim 14, wherein an outer perimeter of the first display substrate is inclined and an inner perimeter of the second display substrate that corresponds to the opening is inclined and overlaps the inclined outer perimeter of the first display substrate.

17. The display device according to claim 16, wherein the inclined outer perimeter of the first display substrate and the inclined inner perimeter of the second display substrate are in contact.

18. The display device according to claim 16, further comprising:
a first pad portion on a part of the inclined outer perimeter of the first display substrate; and
a second pad portion on a part of the inclined inner perimeter of the second display substrate,
wherein the first pad portion and the second pad portion in contact with each other such that the first display substrate and the second display substrate are electrically connected to each other.

19. The display device according to claim 18, further comprising:
a third pad portion on an outer perimeter of the second display substrate;
a fourth pad portion on the outer perimeter of the second display substrate; and
a pad wire having a first end that is connected to the second pad portion and a second end that is connected to the third pad portion,
wherein the third pad portion receives a signal that drives the first display substrate and the fourth pad portion receives a signal that drives the second display substrate.

20. The display device according to claim 19, wherein the second display substrate comprises:
a lower display substrate; and
an upper display substrate on the lower display substrate, the upper display substrate including the opening in which the first display substrate is disposed.

21. The display device according to claim 20, wherein the pad wire is between the lower display substrate and the upper display substrate.

22. The display device according to claim 19, wherein the pad wire and the third pad portion extend along a lower surface of the second display substrate and the fourth pad portion is on an upper surface of the second display substrate that is opposite the lower surface of the second display substrate.

23. The display device according to claim 14, wherein the display device is a head-mounted display device that is configured to implement virtual reality or augmented reality.
